(19) United States
(12) Patent Application Publication
(10) Pub. No.: US 2017/0134700 A1
(43) Pub. Date: May 11, 2017

(54) IMAGE SURVEILLANCE DEVICE

(71) Applicant: VIVOTEK INC., New Taipei City (TW)

(72) Inventors: Hsiang-Lin Hsu, New Taipei City (TW); Hsuen-Chun Lu, New Taipei City (TW)

(21) Appl. No.: 15/284,558

(22) Filed: Oct. 4, 2016

(30) Foreign Application Priority Data
Nov. 5, 2015 (TW) 104136557

(51) Int. Cl. H04N 7/18; H05K 5/02; H05K 5/03; H05K 7/20; H04N 5/225; H05B 3/84

(52) U.S. Cl. CPC H04N 7/183; H04N 5/2252; H04N 5/2254; H05B 3/84; H05K 5/03; H05K 7/20145; H05K 7/20154; H05K 7/20436; H05K 5/0256

(57) ABSTRACT

An image surveillance device includes a casing, a lens module, a heater, a heat conduction sheet and a fan module. The lens module is disposed in the casing for capturing images. The heater is used for generating thermal energy. The heat conduction sheet is attached to the lens module and the heater for conducting the thermal energy to the lens module. The fan module is disposed on the heater for guiding airflow to cause heat convection in the casing. Accordingly, the present invention can solve the prior art problem that the thermal energy is accumulated on the heater, so as to greatly improve the thermal energy efficiency of the image surveillance device.

### BACKGROUND OF THE INVENTION

### 1. Field of the Invention

The present invention relates to an image surveillance device, and more specifically, to an image surveillance device for conducting thermal energy generated by a heater to a lens module via a heat conduction sheet.

### 2. Description of the Prior Art

In general, an image surveillance device is mainly applied to outdoor video monitoring. That is, the image surveillance device is usually operated in an environment having a wide temperature variation range (about −40° C.˜50° C.). Accordingly, there are usually a heater and a heat-dissipating fin structure installed in the image surveillance device. A conventional design involves disposing a heater on a major component (e.g. a lens module) in the image surveillance device for heating the major component to its working temperature (e.g. higher than −10° C.). However, since the aforesaid design lacks a preferable heat conduction mechanism and the heating direction of the heater is not unidirectional, it may cause heat accumulation on the surface of the heater so as to reduce the thermal energy efficiency of the image surveillance device. Thus, the image surveillance device could not be heated to its working temperature quickly when the temperature around the image surveillance device is too low.

### SUMMARY OF THE INVENTION

The present invention provides an image surveillance device. The image surveillance device includes a casing, a lens module, a casing, a heater, a heat conduction sheet, and a fan module. The lens module is disposed in the casing for capturing images. The heater is used for generating thermal energy. The heat conduction sheet is attached to the lens module and the heater for conducting the thermal energy generated by the heater to the lens module. The fan module is disposed on the heater for guiding airflow to cause heat convection in the casing.

The present invention further provides an image surveillance device. The image surveillance device includes a lens module, an illumination module, a heater, a fan device, a casing, a first transparent cover, and a second transparent cover. The lens module is used for capturing images. The illumination module is disposed at a side of the lens module for providing light to the lens module. The heater is disposed on the casing for generated thermal energy. The fan device is disposed on the heater for generating airflow to conduct the thermal energy generated by the heater. The casing has a first space and a second space formed therein. A first channel, a second channel, and a third channel are formed in the casing corresponding to an air outlet of the fan module. The lens module is contained in the first space. The illumination module is contained in the second space. The first channel is communicated with the first space for guiding the airflow generated by the fan module to flow toward the lens module. The first transparent cover is disposed on the casing and faces the lens module. The second channel is communicated with the first space for guiding the airflow to flow toward the first transparent cover. The second transparent cover is disposed on the casing and faces the illumination module. The third channel is communicated with the second space for guiding the airflow to flow toward the second transparent cover.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an image surveillance device according to an embodiment of the present invention.

FIG. 2 is a diagram of the image surveillance device in FIG. 1 at another viewing angle.

FIG. 3 is a cross-sectional diagram of the image surveillance device in FIG. 1 along a cross-sectional line A-A.

FIG. 4 is a partial internal enlarged diagram of the image surveillance device in FIG. 2.

FIG. 5 is a cross-sectional diagram of an image surveillance device according to another embodiment of the present invention.

### DETAILED DESCRIPTION

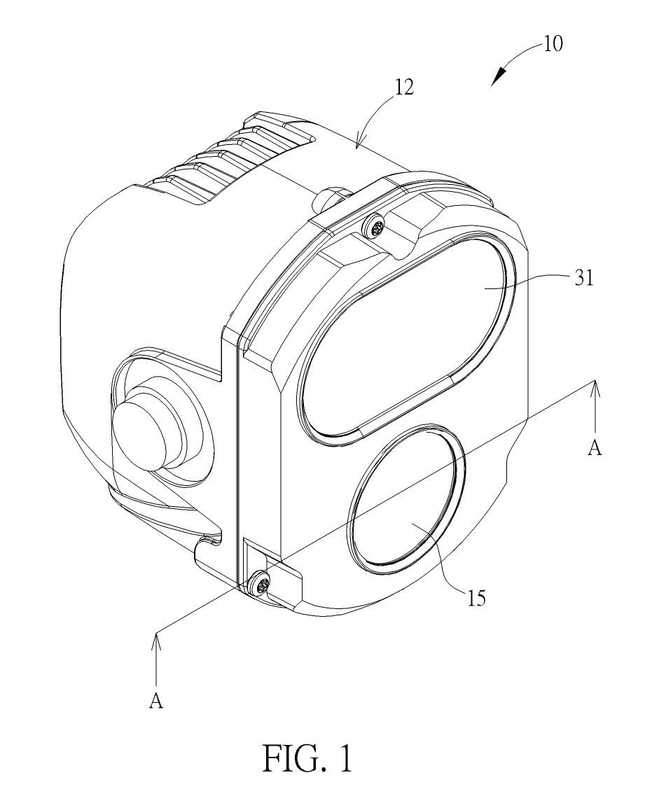

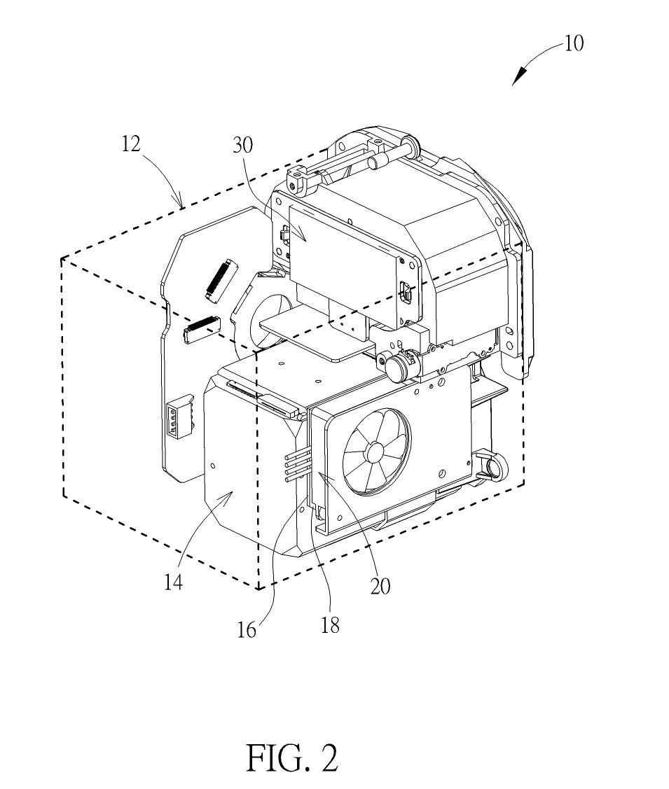

Please refer to FIG. 1 and FIG. 2. FIG. 1 is a diagram of an image surveillance device 10 according to an embodiment of the present invention. FIG. 2 is a diagram of the image surveillance device 10 in FIG. 1 at another viewing angle. For clearly showing the internal structural design of the image surveillance device 10, the casing 12 is briefly depicted by dotted lines in FIG. 2. As shown in FIG. 1 and FIG. 2, the image surveillance device 10 includes a casing 12, a lens module 14, a heat conduction sheet 16, a heater 18, and a fan module 20. The lens module 14 is disposed in the casing 12 and is used to capture images for subsequent image processing (e.g. image surveillance). The heat conduction sheet 16 is attached to the lens module 14 and is preferably made of material with high heat conductivity, such as heat conductive silica gel. The heater 18 is disposed on the heat conduction sheet 16 for generating thermal energy. Accordingly, the thermal energy generated by the heater 18 could be conducted to the lens module 14 quickly via high heat conductivity of the heat conduction sheet 16.

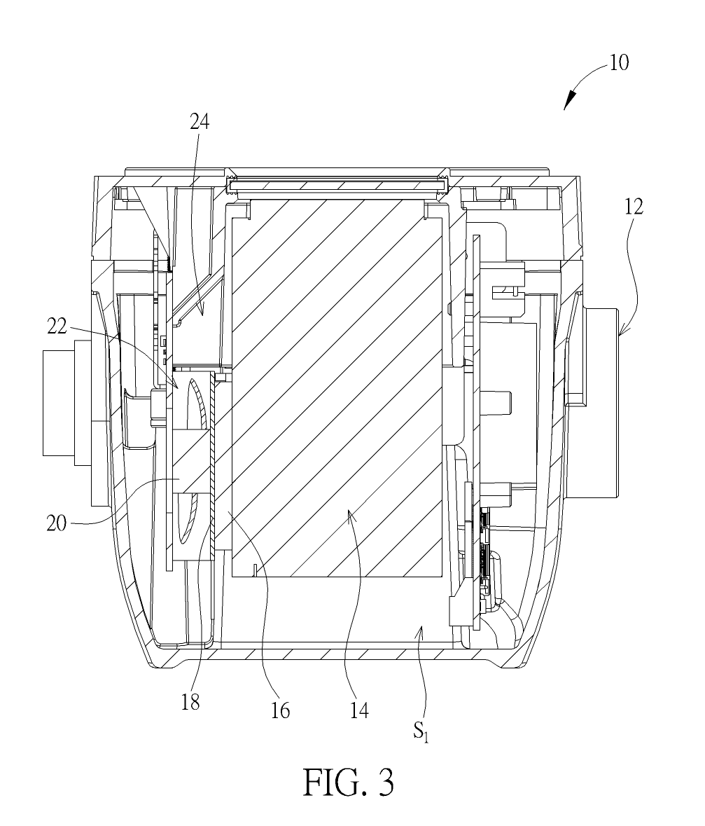

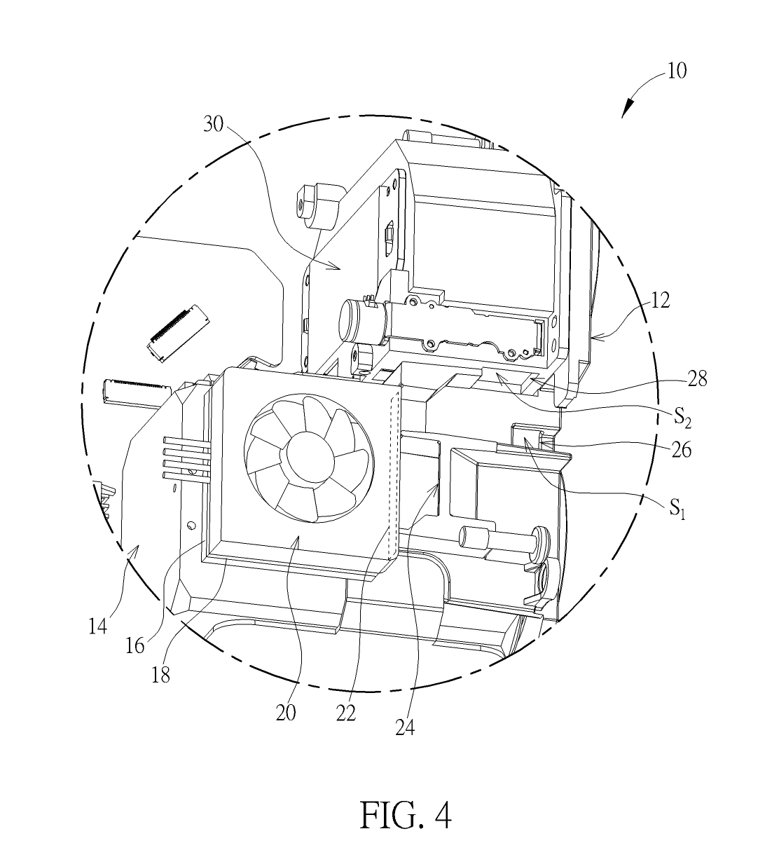

More detailed description for the design of the fan module 20 is provided as follows. Please refer to FIG. 1, FIG. 2, FIG. 3, and FIG. 4. FIG. 3 is a cross-sectional diagram of the image surveillance device 10 in FIG. 1 along a cross-sectional line A-A. FIG. 4 is a partial internal enlarged diagram of the image surveillance device 10 in FIG. 2. As shown in FIG. 1, FIG. 2, FIG. 3, and FIG. 4, the fan module 20 is disposed on the heater 18. In this embodiment, the fan module 20 could be preferably a metal fan device, meaning that the major components (e.g. fan blade, fan frame, etc.) of the fan module 20 are made of metal material for improving the heat conduction efficiency of the fan module 20. In practical application, as shown in FIG. 3 and FIG. 4, a first channel 24 is formed in the casing corresponding to an air outlet 22 of the fan module 20. The casing 12 has a first space S₁ formed therein for containing the lens module 14. The first channel 24 is communicated with the first space S₁ of the casing 12 for guiding airflow generated by the fan module 20 to flow toward the lens module 14.

For improving the internal heat conduction efficiency of the image surveillance device 10, in this embodiment, a second channel 26 and a third channel 28 could be formed in the casing 12 corresponding to the air outlet 22 of the fan module 20 as shown in FIG. 1, FIG. 3, and FIG. 4. The image surveillance device 10 could further include a first transparent cover 15, an illumination module 30, and a second transparent cover 31. The first transparent cover 15 is disposed on the casing 12 and faces the lens module 14 for protection. The second channel 26 is communicated with the first space S₁ for guiding the airflow generated by the fan module 20 to flow toward the first transparent cover 15. The illumination module 30 is contained in a second space S₂ of the casing 12 and could be a light emitting device (preferably an infrared light emitting diode, but not limited thereto, meaning that the illumination module 30 could be other type of light emitting diode, such as a visible light emitting diode) commonly applied to a conventional image surveillance device, so as to provide auxiliary light to capture clear images even if the image surveillance device 10 is operated in a dark environment (e.g. indoor or in the night). The second transparent cover 31 is disposed on the casing 12 and faces the illumination module 30 for protection. The third channel 28 is communicated with the second space S₂ for guiding the airflow generated by the fan module 20 to flow toward the second transparent cover 31.

Via the aforesaid designs, when the image surveillance device 10 is in an environment with an excessively-low temperature (e.g. lower than −10° C.), the image surveillance device 10 could activate the heater 18 and the fan module 20. Accordingly, the thermal energy generated by the heater 18 could be conducted to the lens module 14 via the high heat conductivity of the heat conduction sheet 16 and could be taken away by the airflow generated by the fan module 20. At this time, the airflow with the thermal energy could flow into the first space S₁ via guidance of the first channel 24 and then flow toward the lens module 14, so as to establish a preferable heat convection mechanism. In such a manner, via the heat conduction design that the heat conduction sheet 16 is attached between the heater 18 and the lens module 14 and the airflow guiding design that the fan module 20 guides the airflow to flow toward the lens module 14 through the first channel 24, the thermal energy generated by the heater 18 could be conducted to the lens module 14 quickly, so that the lens module 14 could be heated to its working temperature (e.g. higher than −10° C.) quickly and work properly. Thus, the present invention could efficiently solve the prior art problem that the thermal energy is accumulated on the surface of the heater, so as to greatly improve the thermal energy efficiency of the image surveillance device 10, and could surely solve the problem that the major components of the image surveillance device 10 cannot work properly due to the excessively-low temperature.

Furthermore, via the airflow guiding design that the fan module 20 guides the airflow to flow toward the first transparent cover 15 through the second channel 26 and flow toward the second transparent cover 31 through the third channel 28, the thermal energy generated by the heater 18 could also be conducted to the first transparent cover 15 and the second transparent cover 31 quickly, so as to achieve the demisting purpose.

To be noted, the aforesaid heat conduction design that the heat conduction sheet 16 is attached between the heater 18 and the lens module 14 and forming of the first channel 24, the second channel 26, and the third channel 28 could be selectively omitted according to the practical application of the image surveillance device 10, so as to further simplify the design of the image surveillance device 10. For example, in another embodiment, the image surveillance device provided by the present invention could only adopt one of the heat conduction design that the heat conduction sheet is attached between the heater and the lens module and the airflow guiding design that the fan module guides the airflow to flow toward the lens module and the transparent covers through the channels respectively, or could just omit the second channel and the third channel for simplifying the channel design of the image surveillance device. As for other derived embodiments, the related description could be reasoned by analogy and omitted herein.

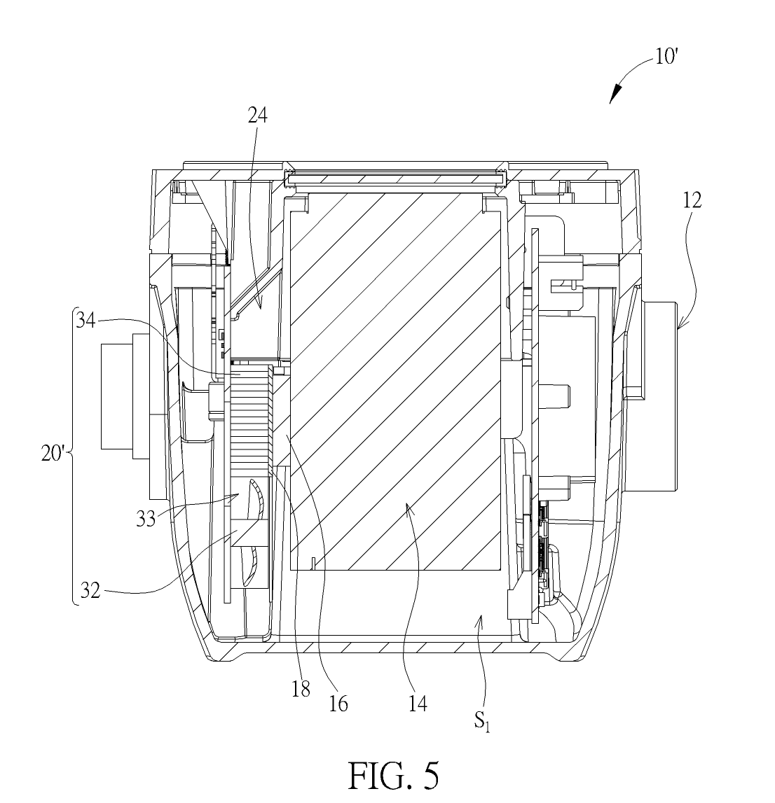

Furthermore, disposal of the fan module and the heater is not limited to the aforesaid embodiment. For example, please refer to FIG. 5, which is a cross-sectional diagram of an image surveillance device 10′ according to another embodiment of the present invention. Components both mentioned in this embodiment and the aforesaid embodiment represent components with similar functions or structures. The major difference between the image surveillance device 10′ and the image surveillance device 10 is the design of the fan module. As shown in FIG. 5, the image surveillance device 10′ includes the casing 12, the lens module 14, the heat conduction sheet 16, the heater 18, and a fan module 20′. In this embodiment, the fan module 20′ includes a plastic fan device 32, of which the major components (e.g. fan blade, fan frame, etc.) are made of plastic material, and a heat-dissipating fin structure 34. The heat-dissipating fin structure 34 is attached to the heater 18 for conducting the thermal energy generated by the heater 18. The plastic fan device 32 is disposed at a side of the heat-dissipating fin structure 34, and an air outlet 33 of the plastic fan device 32 faces the heat-dissipating fin structure 34. The first channel 24 is formed in the casing 12 corresponding to the heat-dissipating fin structure 34. Accordingly, the thermal energy generated by the heater 18 could be conducted to the lens module 14 via the high heat conductivity of the heat conduction sheet 16. Simultaneously, the thermal energy generated by the heater 18 could also be taken by the heat-dissipating fin structure 34, and then be conducted to the lens module 14 via guidance of the airflow generated by the plastic fan device 32 through the first channel 24, so as to establish a preferable heat convection mechanism in the casing 12. As for the related description for other components (e.g. the casing 12, the lens module 14, the heat conduction sheet 16, and the heater 18) of the image surveillance device 10′, it could be reasoned by analogy according to the aforesaid embodiment and omitted herein.

Compared with the prior art, the present invention adopts the heat conduction design that the heat conduction sheet is attached between the heater and the lens module and the airflow guiding design that the fan module guides the airflow to flow toward the lens module and the transparent covers through the channels, so that the thermal energy generated by the heater could be conducted to the lens module and the transparent covers quickly. In such a manner, the present invention could efficiently solve the prior art problem that the thermal energy is accumulated on the surface of the heater, so as to improve the thermal energy efficiency of the image surveillance device, solve the problem that the major components of the image surveillance device cannot work properly due to the excessively-low temperature, and achieve the demisting purpose.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An image surveillance device comprising:
a casing;
a lens module disposed in the casing for capturing images;
a heater for generating thermal energy;
a heat conduction sheet attached to the lens module and the heater for conducting the thermal energy generated by the heater to the lens module; and
a fan module disposed on the heater for guiding airflow to cause heat convection in the casing.

2. The image surveillance device of claim 1, wherein the fan module is a metal fan device, a first channel is formed in the casing corresponding to an air outlet of the fan module, the casing has a first space formed therein for containing the fan module, and the first channel is communicated with the first space for guiding the airflow generated by the fan module to flow toward the lens module.

3. The image surveillance device of claim 2, wherein a second channel is further formed in the casing corresponding to the air outlet of the fan module, the image surveillance device further comprises a first transparent cover, the first transparent cover is disposed on the casing and faces the lens module, and the second channel is communicated with the first space for guiding the airflow generated by the fan module to flow toward the first transparent cover.

4. The image surveillance device of claim 3, wherein a third channel is further formed in the casing corresponding to the air outlet of the fan module, the image surveillance device further comprises an illumination module and a second transparent cover, the illumination module is contained in a second space of the casing for providing light to the lens module, the second transparent cover is disposed on the casing and faces the illumination module, and the third channel is communicated with the second space for guiding the airflow generated by the fan module to flow toward the second transparent cover.

5. The image surveillance device of claim 2, wherein a second channel is further formed in the casing corresponding to the air outlet of the fan module, the image surveillance device further comprises an illumination module and a transparent cover, the illumination module is contained in a second space of the casing for providing light to the lens module, the transparent cover is disposed on the casing and faces the illumination module, and the second channel is communicated with the second space for guiding the airflow generated by the fan module to flow toward the transparent cover.

6. The image surveillance device of claim 1, wherein the fan module comprises a plastic fan device and a heat-dissipating fin structure, the heat-dissipating fin structure is attached to the heater for conducting the thermal energy generated by the heater, the plastic fan device is disposed at a side of the heat-dissipating fin structure, an air outlet of the plastic fan device faces the heat-dissipating fin structure, the casing has a first space formed therein for containing the lens module, and a first channel is communicated with the first space for guiding the airflow to pass through the heat-dissipating fin structure from the air outlet and flow toward the lens module.

7. The image surveillance device of claim 6, wherein a second channel is further formed in the casing corresponding to the heat-dissipating fin structure, the image surveillance device further comprises a first transparent cover, the first transparent cover is disposed on the casing and faces the lens module, and the second channel is communicated with the first space for guiding the airflow to pass through the heat-dissipating fin structure from the air outlet and flow toward the first transparent cover.

8. The image surveillance device of claim 7, wherein a third channel is further formed in the casing corresponding to the heat-dissipating fin structure, the image surveillance device further comprises an illumination module and a second transparent cover, the illumination module is contained in a second space of the casing for providing light to the lens module, the second transparent cover is disposed on the casing and faces the illumination module, and the third channel is communicated with the second space for guiding the airflow to pass through the heat-dissipating fin structure from the air outlet and flow toward the second transparent cover.

9. The image surveillance device of claim 6, wherein a second channel is further formed in the casing corresponding to the heat-dissipating fin structure, the image surveillance device further comprises an illumination module and a transparent cover, the illumination module is contained in a second space of the casing for providing light to the lens module, the transparent cover is disposed on the casing and faces the illumination module, and the second channel is communicated with the second space for guiding the airflow to pass through the heat-dissipating fin structure from the air outlet and flow toward the transparent cover.

10. An image surveillance device comprising:
a lens module for capturing images;
an illumination module disposed at a side of the lens module for providing light to the lens module;
a heater disposed on the casing for generated thermal energy;
a fan device disposed on the heater for generating airflow to conduct the thermal energy generated by the heater;
a casing having a first space and a second space formed therein, a first channel, a second channel, and a third channel being formed in the casing corresponding to an air outlet of the fan module, the lens module being contained in the first space, the illumination module being contained in the second space, the first channel being communicated with the first space for guiding the airflow generated by the fan module to flow toward the lens module;
a first transparent cover disposed on the casing and facing the lens module, the second channel being communicated with the first space for guiding the airflow to flow toward the first transparent cover; and
a second transparent cover disposed on the casing and facing the illumination module, the third channel being communicated with the second space for guiding the airflow to flow toward the second transparent cover.

11. The image surveillance device of claim 10, wherein the fan module is a metal fan device.

12. The image surveillance device of claim 10, wherein the fan module comprises a plastic fan device and a heat-dissipating fin structure, the heat-dissipating fin structure is attached to the heater for conducting the thermal energy, the plastic fan device is disposed at a side of the heat-dissipating fin structure, the air outlet of the plastic fan device faces the heat-dissipating fin structure, and the first channel is formed in the casing corresponding to the heat-dissipating fin structure for guiding the airflow to pass through the heat-dissipating fin structure from the air outlet and flow toward the lens module.
